(19) United States
(12) Patent Application Publication
(10) Pub. No.: US 2024/0127427 A1
(43) Pub. Date: Apr. 18, 2024

(54) SYSTEMS AND METHODS FOR GENERATING FLOORPLANS FROM LARGE AREA SCANNING

(71) Applicant: MappedIn Inc., Waterloo (CA)

(72) Inventors: Erkang Wei, Waterloo (CA); James Nathan Swidersky, Kitchener (CA); Claudio Sa, Waterloo (CA)

(21) Appl. No.: 18/393,031

(22) Filed: Dec. 21, 2023

Related U.S. Application Data
(60) Provisional application No. 61/336,817, filed on Jan. 27, 2010.

(51) Int. Cl. G06T 7/00; G06F 30/13; G06T 17/05; G06T 19/00; G06T 19/20

(52) U.S. Cl. CPC G06T 7/001; G06F 30/13; G06T 17/05; G06T 19/006; G06T 19/20; G06T 2207/10028; G06T 2207/30108; G06T 2210/04; G06T 2219/2012

(57) ABSTRACT

A scanning device and methods for generating floorplans by combining different scans of a large area are provided. During scanning, a preview of the scanned area is shown on a display of the scanning device to assist a user to orientate the scanning device to scan the space. The scanning device is further configured to display instructions/prompts to the user to assist in scanning. For example, the device may prompt the user to pause scanning when device memory becomes depleted. A method for generating a floorplan from multiple scans comprises pausing a first scan a reference point and commencing a second scan at the reference. The reference point is used to combine the first scan data and the second scan data to generate an overall floorplan of the scanned space.

### TECHNICAL FIELD

The embodiments disclosed herein relate to creating floorplans of large indoor spaces, and, in particular to systems and methods for creating accurate floorplans from scanning large indoor spaces.

### INTRODUCTION

Floorplans are used for designing and remodeling indoor spaces. In addition, floorplans may be used as maps for wayfinding within a building. Typically, floorplans are created by an illustrator/designer/architect who views the area to be mapped and generates the floorplan using pen-and-paper or computer-assisted drawing techniques. A floorplan may also be generated using existing architectural or design drawings (e.g., CAD drawings) as a basis or starting point. However, for many indoor spaces, there may not be CAD or architectural drawings available.

With the advent of mobile devices having cameras, light and depth sensors (e.g., smartphones, tablet devices), methods of generating floorplans by scanning a room using the device's cameras and sensors have been devised (e.g., Room Plan API). This enables relatively quick and easy generation of floorplans without requiring specialized equipment or design drawings. Such devices may be configured to generate floorplans in real time, while scanning a room, and also automatically identify or annotate room features (e.g., doors, windows) and objects (e.g., chairs, desks) as part of the floorplan (see for example, United States Patent Publication No. 2021/0225090).

A limitation of existing systems and methods is that concurrent scanning of a room, and generation of the floorplan in real time, is a very computationally intensive process, in particular, when performed on mobile devices having limited system resources i.e., processing power, memory and power supply (battery life). The high consumption of system resources limits the size of the area that can be scanned and mapped at one time to relatively small areas, such as single rooms. Accordingly, to generate a floorplan of a large area (e.g., a floor of a building having multiple rooms, hallways, etc.) each room or space must be individually scanned and combined.

Further difficulties arise when combining or stitching multiple scanned rooms/spaces together to generate a floorplan of a larger area, such as an entire floor of a building. For example, incongruities and/or gaps between individual room scans can translate to incongruities or gaps in the overall floorplan when the individual scans are combined.

Further problems arise during automatic identification and annotation of room features and objects. Room features and objects may not be recognized at all, or identified as a false positive (e.g., a display screen or white board may be misidentified as a window). Architectural features such as columns may be identified as slanted walls and corners may not be at the correct angle. Artefacts may also be introduced during scanning, for example, extra or redundant wall segments may be introduced.

Accordingly, there is a need for methods for creating accurate floorplans from large area scanning.

### SUMMARY

Provided is a system and methods for generating floorplans by combining scans of different areas of a larger space.

According to an embodiment, there is a method for generating a floorplan from multiple scans. The method comprises commencing a first scan of a space by a scanning device; pausing the first scan at a reference point; storing first scan data including the reference point; commencing a second scan of the space at the reference point, wherein the second scan covers an area in the space not scanned in first scan; stopping the second scan; storing second scan data including the reference point; and combining the first scan data and the second scan data at the reference point to generate the floorplan.

The method may further include identifying an architectural feature of the space as a starting point or identifying an architectural feature of the space as the reference point.

The method may further include displaying, on a display of the scanning device, a prompt to direct sensors of the scanning device to an architectural feature in the space. Other prompts or notifications may be presented to facilitate scanning. For example, the method may further comprise displaying, a prompt that a memory of the scanned device is depleting or displaying a prompt to a user to pause the first scan.

The method may further comprise displaying a preview of a 2D floorplan of the space on a display of the scanning device during the first scan and the second scan. The method may comprise providing an editor interface for editing one or more of: the first scan data and the second scan data.

According to another embodiment there is a scanning device for large area scanning. The scanning device comprises one or more sensors for scanning an space, a display, a storage unit for storing scan data, a memory for storing processor-executable instructions and one or more processors for executing the instructions.

Other aspects and features will become apparent, to those ordinarily skilled in the art, upon review of the following description of some exemplary embodiments.

### BRIEF DESCRIPTION OF THE DRAWINGS

The drawings included herewith are for illustrating various examples of articles, methods, and apparatuses of the present specification. In the drawings:

FIG. 1 is a block diagram of a scanning device, according to an embodiment;

FIGS. 2A-2G are exemplary user interfaces generated by the scanning application of FIG. 1, according to several embodiments;

FIG. 2H is a diagram of recommencing a paused/stopped scan, according to an embodiment;

FIG. 3A is diagrams of manual corrections to wall inaccuracies in a floorplan editor, according to an embodiment;

FIG. 3B is diagrams of automatic corrections to wall inaccuracies in a floorplan editor, according to an embodiment;

FIG. 3C is diagrams of automatic corrections to wall overlap inaccuracies in a floorplan editor, according to an embodiment;

FIG. 3D is diagrams of automatic corrections to wall spacing inaccuracies in a floorplan editor, according to an embodiment;

FIG. 4A is a diagram of a scanned space including a column, according to an embodiment;

FIG. 4B is a 2D floorplan of the scanned space of FIG. 4A in a floorplan editor;

FIG. 4C is a corrected floorplan of the scanned space of FIG. 4A after manual correction in the floorplan editor;

FIG. 5A. is an exemplary user interface for feature editing in a floorplan editor, according to an embodiment;

FIG. 5B is an exemplary user interface for combining scans in a floorplan editor, according to an embodiment; and

FIG. 6 is a flow chart of a method for combining scans of multiple spaces to create a floorplan, according to an embodiment.

### DETAILED DESCRIPTION

Various apparatuses or processes will be described below to provide an example of each claimed embodiment. No embodiment described below limits any claimed embodiment and any claimed embodiment may cover processes or apparatuses that differ from those described below. The claimed embodiments are not limited to apparatuses or processes having all of the features of any one apparatus or process described below or to features common to multiple or all of the apparatuses described below.

One or more systems and methods described herein may be implemented in computer programs executing on programmable computers, each comprising at least one processor, a data storage system (including volatile and non-volatile memory and/or storage elements), at least one input device, and at least one output device. For example, and without limitation, the programmable computer may be a programmable logic unit, a mainframe computer, server, and personal computer, cloud-based program or system, laptop computer, personal data assistance, cellular telephone, smartphone, or tablet device.

Each program is preferably implemented in a high-level procedural or object oriented programming and/or scripting language to communicate with a computer system. However, the programs can be implemented in assembly or machine language, if desired. In any case, the language may be a compiled or interpreted language. Each such computer program is preferably stored on a storage media or a device readable by a general or special purpose programmable computer for configuring and operating the computer when the storage media or device is read by the computer to perform the procedures described herein.

A description of an embodiment with several components in communication with each other does not imply that all such components are required. On the contrary a variety of optional components are described to illustrate the wide variety of possible embodiments of the present invention.

Further, although process steps, method steps, algorithms or the like may be described (in the disclosure and/or in the claims) in a sequential order, such processes, methods and algorithms may be configured to work in alternate orders. In other words, any sequence or order of steps that may be described does not necessarily indicate a requirement that the steps be performed in that order. The steps of processes described herein may be performed in any order that is practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article.

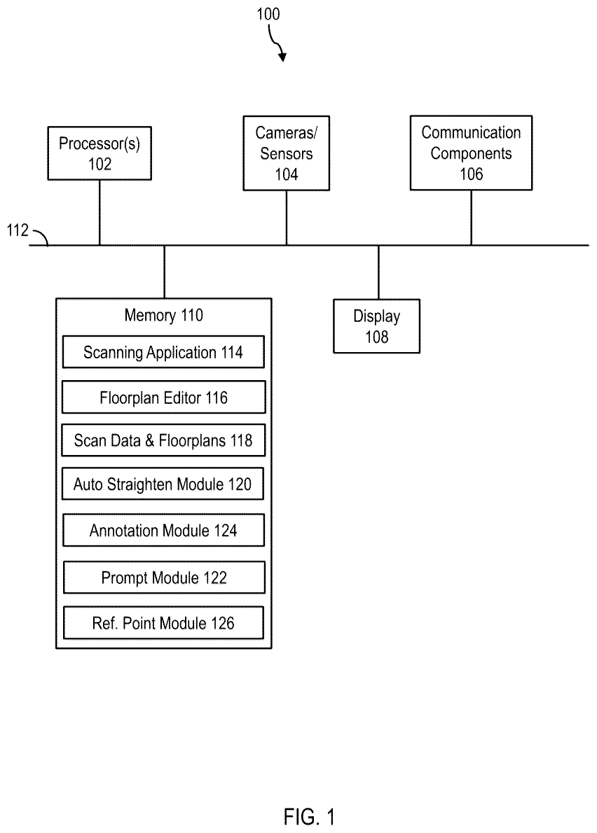

Referring to FIG. 1, shown therein is a block diagram of a scanning device 100, according to an embodiment. The device 100 may be a mobile phone (i.e., a smartphone), a tablet device, or the like. The device 100 includes one or more processing units 102 (e.g., microprocessors, CPUs, GPUs). The device 100 includes a plurality of sensors 104 (e.g., cameras, light sensors, depth sensors, accelerometers, gyroscopes, GPS). The device 100 includes wireless communication components 106 (e.g., cellular GSM, CDMA, Wi-Fi, Bluetooth) for connecting to communication networks and/or peripheral devices (e.g., AR/VR displays). The device 100 includes at least one display 108 (e.g., LED, LCD) screen. The display screen 108 may be a touchscreen configured as a display and/or an input device. The device 100 includes a memory 110 for storing a plurality of applications and software modules. The device 100 includes one or more communication buses 112 for interconnecting and controlling communications between the device 100 components 102, 104, 106, 108, 110.

The memory 110 includes a scanning application 114 configured for scanning an indoor space (e.g., a room) and outputting 2D and/or 3D floorplans of the space. The scanning application 114 may implement the Room Plan Swift API made available by Apple® to generate a 3D model of the space that contains data such as walls, windows, doors, tables, storage cabinets, etc. The Room Plan Swift API utilizes the cameras/sensors 104 of the device 100 to create a 3D floor plan of a scanned space, including identifying features/characteristics such as dimensions, walls, entrances/exits, windows and types of furniture (e.g., chairs, desks, cabinets). The scanning application 114 is further configured to output a 2D top-down floorplan of the space that can be edited, corrected and/or annotated as described below.

Scan data and 2D floorplans 118 generated by the scanning application 114 are stored. Scan data includes the 3D floor plan of the scanned space including the identified features/characteristics of the scanned space and reference points (i.e., start and end points of the scan) According to various embodiments, the reference points include, or are associated with, one or more identified features/characteristics of the scanned space.

The memory 110 includes a prompt module 122 for displaying prompts on the display 108 during scanning of the space. The prompts may instruct a user to point/orient the cameras/sensors 104 of the device 100 in a particular direction or toward a particular feature or reference point. A reference point module 126 generates a ghost image of stored reference points to superimpose on the view captured by the cameras/sensors 104. Reference points include features of the space such as doors/entrances, windows, walls, etc. that are automatically or manually identified during a scan.

The memory 110 includes a floorplan editor application 116 for editing the 2D floorplans of the scanned space. The floorplan editor 116 may be automatically executed upon completion of a scan by the scanning application 114. The floorplan editor 116 receives the scan data and floorplans 118 generated by the scanning application 114, upon completion of a scan. The floorplan editor 116 generates a user interface on the display 108 for editing, correcting and/or annotating the 2D top-down representation of the space to generate a floorplan of the space.

An auto straighten module 120 operates with the floorplan editor 116 to automatically straighten lines (e.g., walls) in the floorplan of the space based on real world unit thresholds. An annotation module 124 operates within the editor module to enable a user to edit and/or annotate features in the floorplan.

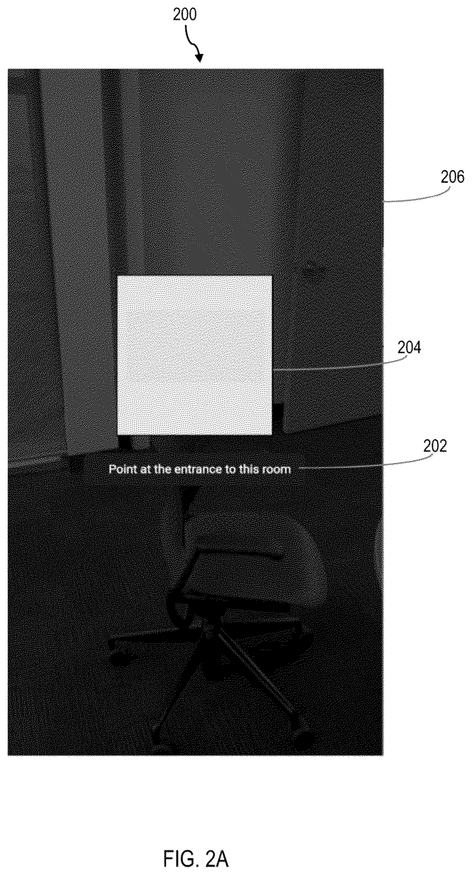

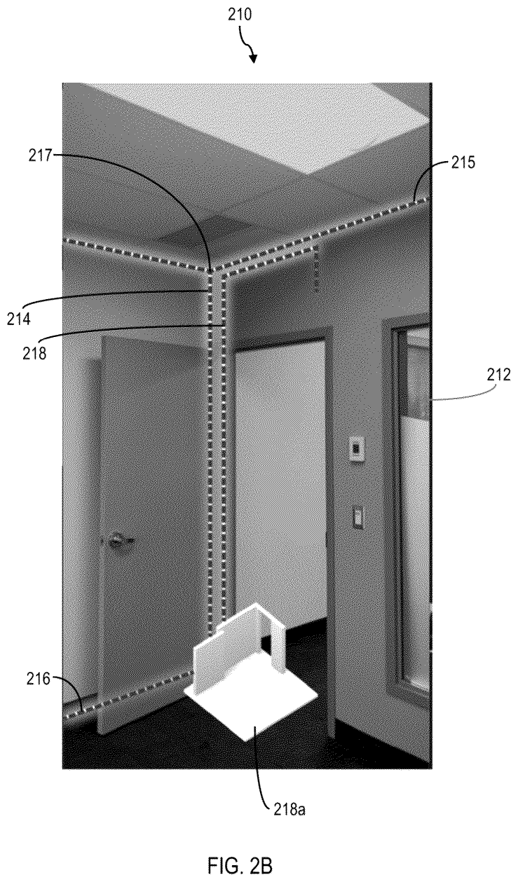

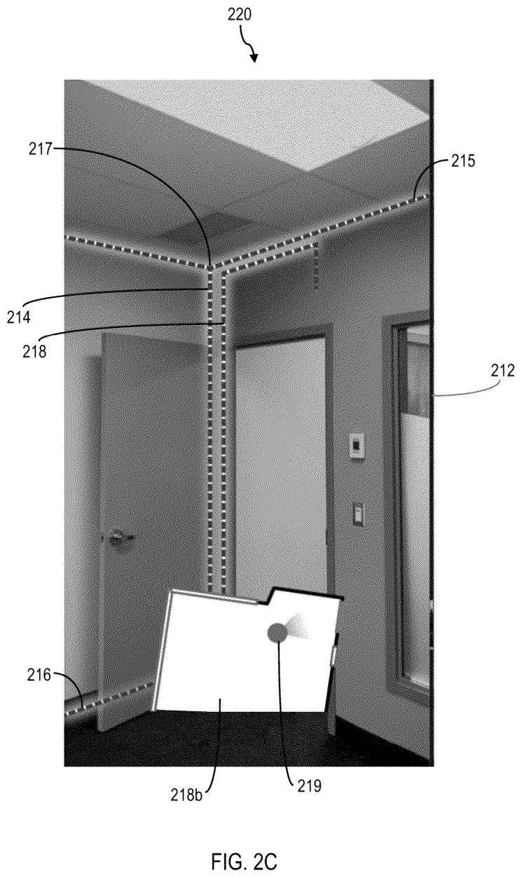

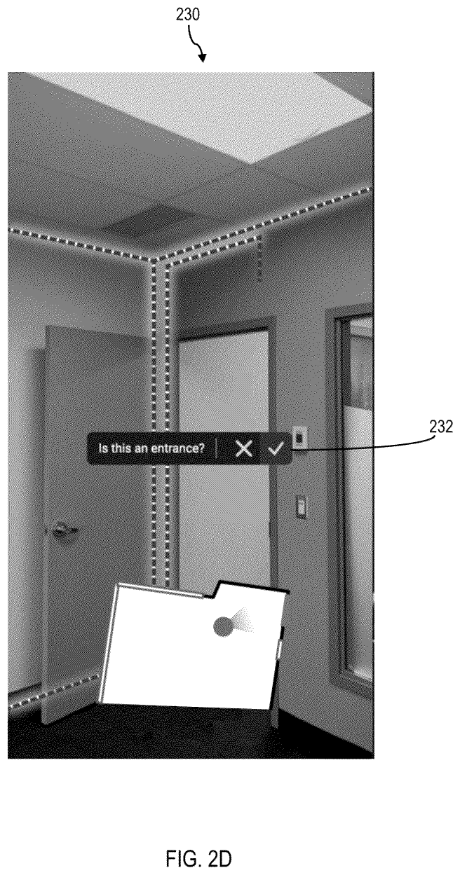

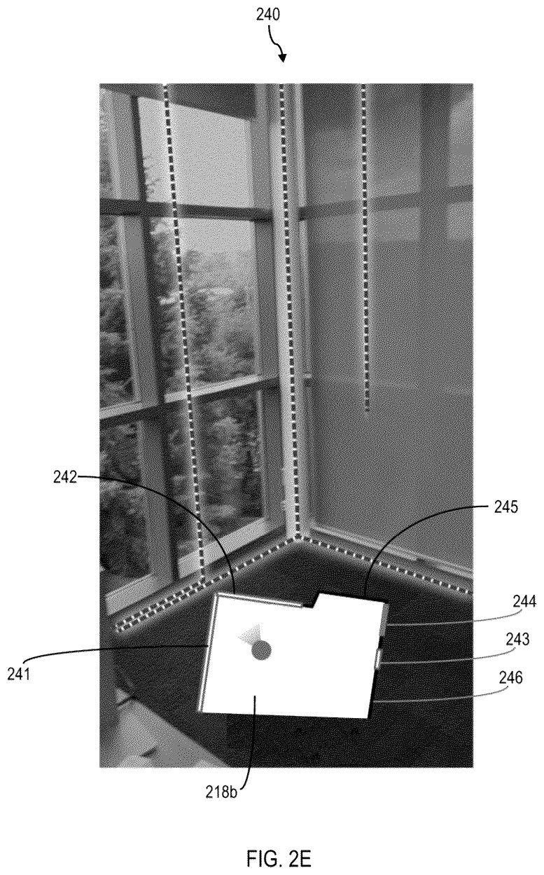

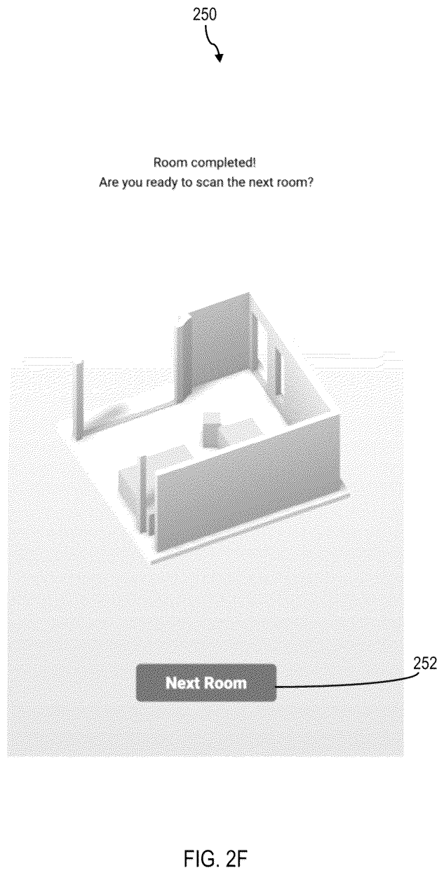

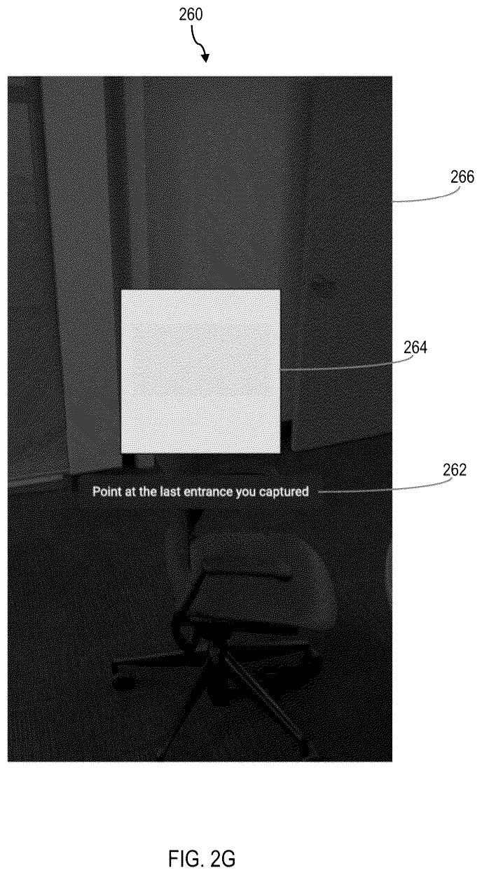

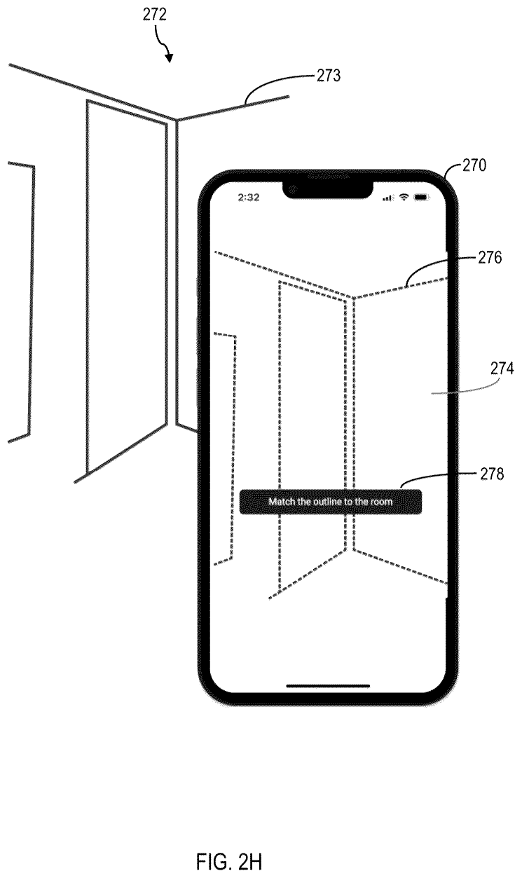

FIGS. 2A-2G show exemplary user interfaces generated by the scanning application 114 when scanning a space. The user interfaces may be presented on a display 108 of the scanning device 100. Generally, the user interfaces show a view, and/or a representation of a scanned space captured by the cameras/sensors 104 of the device 100. Typically, the rear-facing cameras/sensors 104 of the device 100 are used for scanning (i.e., cameras/sensors 104 disposed on a surface of the device 100 opposite the display 108), so that the view captured by the cameras/sensors 104 can be viewed on the display 108 during the scan.

Referring to FIG. 2A, shown therein is an exemplary user interface 200 of a “start screen” of the scanning application 114, according to an embodiment. The user interface 200 may be displayed upon executing the scanning application 114.

The user interface 200 includes a prompt 202 instructing the user to point/orient the cameras/sensors 104 of the device 100 at a feature of the space to commence the scan. For example, the prompt 202 may instruct the user to orient the device 100 toward an entrance to the space (as shown) or to another feature such as a top edge of a wall. The prompt 202 may include an instructional animation or diagram 204 related to the prompt 202. For example, if the prompt 202 instructs the user to point the camera at a top edge of a wall, the animation 204 may show an arrow or device moving upward. The user interface 200 may display a camera view 206 captured by the cameras/sensors 104. The camera view 206 may be tinted or obscured with the prompt 202 and the animation 204 overlayed.

Upon pointing/orienting the cameras/sensors 104 toward the feature instructed by the prompt 204, scanning commences. The scanning application 114 utilizes the Room Plan Swift API to automatically commence the scan once the feature described in the prompt 202 is captured by the device's camera and visible on the camera view 206.

Referring to FIGS. 2B and 2C, shown therein are exemplary user interfaces 210, 220 generated by the scanning application 114 during scanning, according to several embodiments. During a scan, the user interfaces 210, 220 display a camera view 212 captured by the cameras/sensors 104. Superimposed on the camera view 212 are outlines of features 214, 215, 216, 217, 218 of the space identified by the Room Plan Swift API. The outlines may include wall edges 214, a ceiling edges 215, floor edges 216, corners 217, an entrance 218, etc. Boundaries of objects within the room (e.g., desks, chairs, etc.) may also be outlined.

To conserve device memory and allow for uninterrupted scanning of a large space, the outlined features 214, 215, 216, 217, 218 that are identified during scanning may be stored in a device storage or in a database and removed from the device memory when the camera/sensors 104 are directed far enough away from the feature and/or when device memory is low. Previously scanned features may be dynamically loaded back into memory for superimposing onto the camera view 212 when the user comes back within a certain distance of the feature (i.e., when the cameras/sensors 104 are redirected toward the previously scanned area/feature in the space).

The user interfaces 210, 220 may further show a floorplan preview 218a, 218b superimposed on the camera view 212. The floorplan preview 218a, 218b may be generated and displayed in real-time as the space is scanned. The preview 218a may be three-dimensional (FIG. 2B) or the preview 218b may be two-dimensional (FIG. 2C). The preview 218a, 218b may be magnified or reduced by the user using, for example, a touch gesture on the display 108.

The floorplan preview 218a, 218b may show scanned features 214, 215, 216, 217, 218 of the space identified by the Room Plan Swift API. The identified features 214, 215, 216, 217, 218 may be dynamically loaded back into memory for display in the preview 218a, 218b when the user comes back within a certain distance of the feature (i.e., when the cameras/sensors 104 are redirected toward the previously scanned feature in the space).

Referring to FIG. 2C, the floorplan preview 218b, may include a direction indicator 219 showing a real time viewing direction of the cameras/sensors 104 during scanning.

Referring to FIG. 2D, shown therein is an exemplary user interface 230 generated by the scanning application 114 during scanning, according to an embodiment. During scanning, a prompt 232 may be displayed for the user to confirm the feature(s) (e.g., walls, entrances, windows, etc.) detected by the RoomPlan Swift API. Confirmation of the feature annotates the scan data to set the identity of the scanned feature in the floorplan that is generated. Manual confirmation of features by the user during the scan may beneficially reduce the time required to manually correct misidentified features after the scan is completed.

Referring to FIG. 2E, shown therein is an exemplary user interface 240 generated by the scanning application 114 during scanning, according to an embodiment. The floorplan preview 218b, may show the various detected features 241, 242, 243, 244, 245, 246 of the space with different styling/color for the user to more easily identify what the feature is. For example, windows 241, 242, 243 may be shown in the preview 218b as an outlined box; entrance 244 may be shown in the preview 218b with light shading; walls 245, 246 may be shown in the preview 218b with dark shading (or black).

Referring to FIG. 2F, shown therein is an exemplary user interface 250 generated by the scanning application 114 upon completion of a scan, according to an embodiment. The scan may be ended several ways. The scanning application 114 may detect that an enclosed space has been entirely scanned, for example, by identifying that a space having adjoining walls, a floor and a ceiling, has been scanned. According to some embodiments, the user may manually end the scan. In some cases, a prompt may be displayed to the user requesting the user to manually pause the scan and save the scan data before the memory is depleted. According to other embodiments, the scanning application 114 may automatically end the scan when the device 100 detects that system resources, in particular memory, is near depletion during the scanning. The user interface 250 includes a touch button 252 to recommence scanning.

Referring to FIG. 2G, shown there is an exemplary user interface 260 generated by the scanning application 114 to recommence scanning, according to an embodiment. The user interface 260 includes a prompt 262 instructing the user to point/orient the cameras/sensors 104 of the device 100 at the last feature (e.g., an entrance) that was scanned. The last scanned feature(s) may be used as an anchor or reference point(s) by the scanning application 114 for stitching together two scanned spaces as described in detail below. Briefly, the last scanned feature(s) in one scan become reference point(s) that is the starting point for a subsequent scan. The user interface 260 may include an instructional animation or diagram 264 related to the prompt 262. For example, the animation 204 may show an arrow pointing toward the last scanned feature/reference point superimposed on the camera view 266.

Referring to FIG. 2H, shown therein is a diagram of recommencing a scan, according to an embodiment. Scanning may be paused/stopped and recommenced for several reasons as noted above. For example, after a space is completely scanned, the scanning application 114 may automatically stop the scan and prompt the user to move to an adjoining space to continue scanning (FIGS. 2F-2G). To recommence a scan, a scanning device 270 is positioned within a space 272. The device 270 may be the device 100 in FIG. 1. The space 272 may be an unscanned space adjacent/adjoining to a previously scanned space. The space 272 may be an unscanned or substantially unscanned portion of a partially scanned space.

Following pausing/stopping of a scan (see FIG. 2F), to recommence scanning, the device 270 may display a ghost image 276 of the previous scan end point or previously scanned features 273 superimposed on the camera view 274. To recommence scanning, the camera view 274 is oriented so that the ghost image 276 on the display aligns with the corresponding actual features of the space 272 to match the camera's last known scanning orientation. When the ghost image 276 is aligned with the actual features 273, the scanning application 114 automatically recommences scanning.

Following scanning, a 2D top-down floorplan is output by the scanning application 114. The floorplan may contain inaccuracies, for example, inaccuracies in wall dimensions and wall alignment relative to other walls. In some embodiments, wall inaccuracies can be addressed during the scanning. A user identifies reference points/anchors on each wall during scanning and the scanning application 114 automatically straightens/aligns the walls based on real world units and conventions/constraints. Examples of real-world conventions/constraints include: adjacent walls are perpendicular (i.e. meet at a 90-degree) angle unless otherwise specified by the user; and opposing walls are parallel unless otherwise specified by the user.

The use of one or more constraints limits the number of possible modifications or ways the floorplan can be edited, compared to free-form editing in CAD programs, may advantageously provide for computer resource savings, in particular conservation of processor 102, memory 110 and battery expenditure.

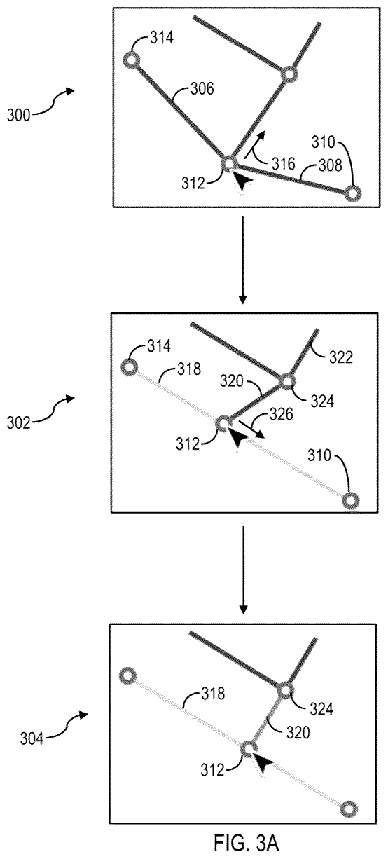

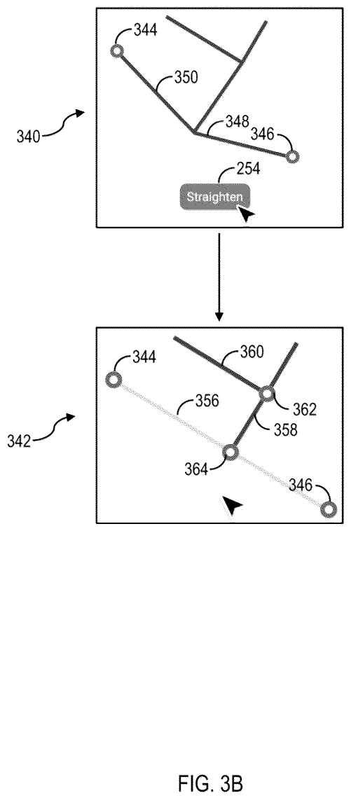

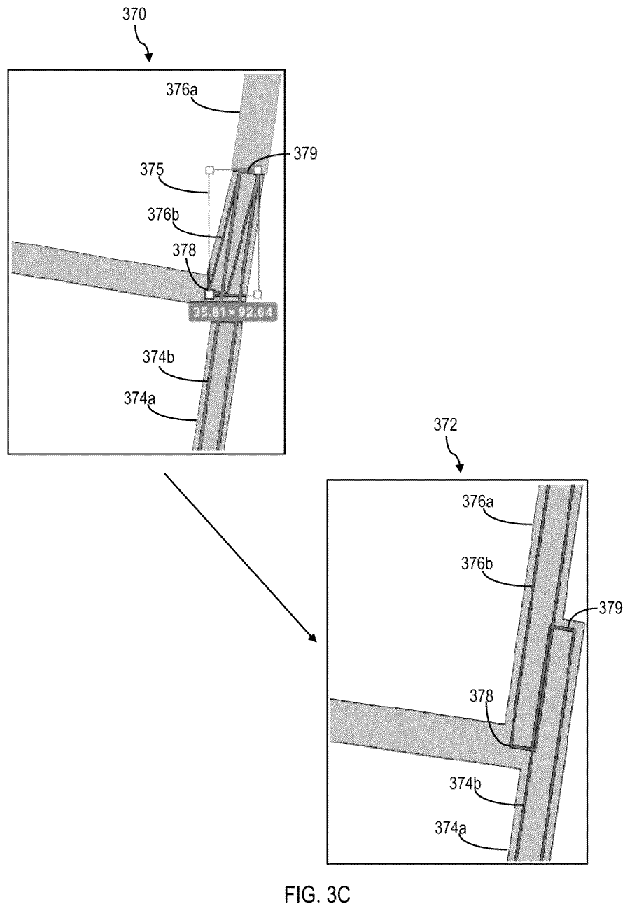

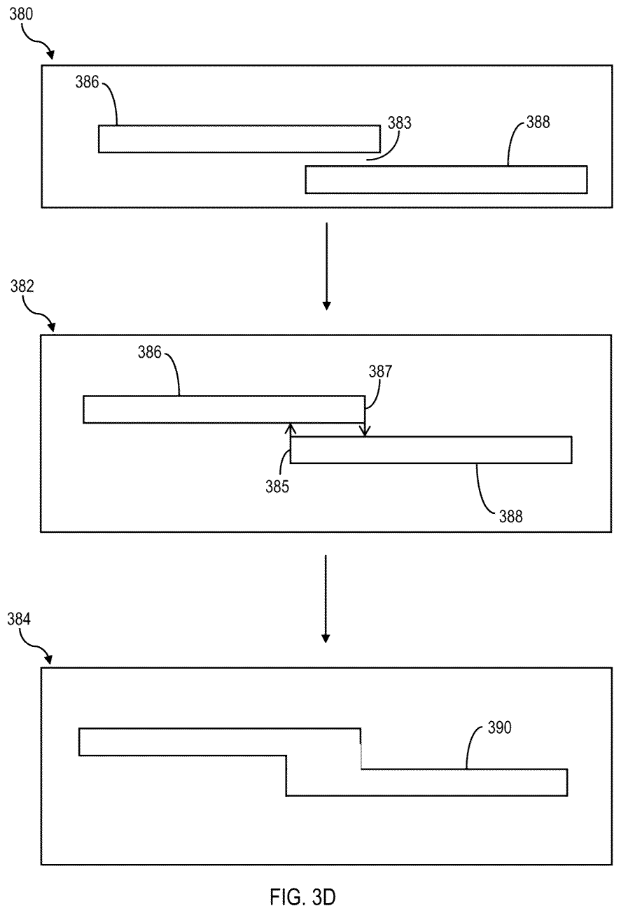

According to other embodiments, the 2D floorplan is editable using the floorplan editor 116 to correct wall inaccuracies. Referring to FIG. 3A, shown therein are diagrams 300, 302, 304 of manual corrections to wall inaccuracies in the floorplan editor 116, according to an embodiment. The floorplan editor 116 displays walls in a 2D floorplan as line segments 306, 308, and corners and ends of walls as vertices 310, 312, 314. Using the floorplan editor 116, a user may adjust walls to correct inaccuracies by selecting and dragging a vertex to move the line segment(s) connected to the vertex. For example, dragging vertex 312 in the direction of arrow 316 will move the line segments 306, 308.

The floorplan editor 116 may be configured to snap together line segments when they are moved such that a straight line is formed by the line segments. For example, when the vertex 312 dragged in the direction of arrow 316, the line segments 306, 308 will snap together to form a straight line 318; and similarly, when the vertex 312 is dragged in the direction of arrow 326, the line segments 320, 322 will snap together to form a straight line 328.

The floorplan editor 116 may be configured to snap together line segments when they are moved such that a ninety-degree angle and/or a 180-degree angle is formed. For example, when vertex 312 is dragged in the direction of arrow 326, line segments 320 and 322 snap together to form a 180-degree angle thereby forming straight line 328. Similarly, when vertex 312 is dragged in the direction of arrow 326, wall segment 320 snaps to straight wall 318 at a 90-degree angle.

Referring to FIG. 3B, shown therein are diagrams 340, 342 of automatic corrections to wall inaccuracies using reference points in the floorplan editor 116, according to an embodiment. A user sets a start vertex 344 and an end vertex 346, as reference points, to straighten the line segments 348, 350 therebetween. After the reference points 344, 346 are selected, a “straighten” button 254 is clicked by the user and the floorplan editor 116 automatically moves the line segments 348, 350 to form a straight line 356. The floorplan editor is configured to find all potential candidate spots for snapping the line segments 348, 350 to straight (180-degree) angles and automatically determines which point is best to snap to based on real world unit thresholds/constraints. Other connected vertices 362, 364 and related walls 358 automatically adjust accordingly. Examples of real-world constraints include: adjacent walls 356, 358 are perpendicular and opposing walls 356, 360 are parallel.

Another type of wall inaccuracy is overlapping wall segments i.e., non-existent overlapping segments between walls, are generated in the floorplan. Referring to FIG. 3C, shown there are diagrams 370, 372 of automatic corrections to wall overlap inaccuracies by the auto straighten module 120, according to an embodiment. Referring to diagram 370, the wall segments 374a, 376a are parallel to each other in a scanned space, however, the 2D top-down floorplan generated by the scanning application 114 includes overlap region 375 between the wall segments 374a, 376a. The diagram 372 shows the corrected wall segments 374a, 376a. The auto straighten module 120 is configured to automatically correct overlap wall overlap inaccuracies computationally using predefined variables for polygon comparison as explained below.

Variables for different classes of polygon objects/features are defined with variable values suited to that particular class. For example, wall segments 374a, 376a are objects of a “wall” class and are defined as polygons with the following variables: minimum wall length; maximum wall length; maximum vertex snap distance; maximum wall angle snap distance; maximum wall close distance; minimum hallway width; maximum hallway width; and maximum hallway snap angle. The auto straighten module 120 attempts to correct the overlap region 375 to make the wall segments 374a, 376a parallel. This can be done is several ways.

(1) The auto straighten module 120 may identify overlapping polygons 374b, 376b, using r-tree or a similar data structure, and merge the overlapping polygons 374b, 376b using known union operations. The original polygon geometries are replaced with a merged geometry.

(2) The auto straighten module 120 may find polygon endpoints 378, 379 that are close (within maximum vertex snap distance of each other) but not touching, and snap each endpoint to the other.

(3) The auto straighten module 120 may find polygon endpoints 378, 379 that are close (within maximum vertex snap distance of each other) but not touching and average the endpoint positions to form a common endpoint between the polygons 374b, 376b.

(4) The auto straighten module 120 may find adjacent pairs of walls 374a, 376a, calculate an angle between the walls 374a, 376a and snap the angle if it falls within the maximum wall angle snap distance of a major angle. Major angles include 90 degrees, 45 degrees, and any angles that appear with high frequency in the floor plan data. Major angles may be modified by the user to allow for more or less strict snapping. To snap to an angle, common points (e.g., endpoint 379) between walls 374a, 376a are used as an origin and attempt to rotate the other endpoints (e.g., endpoint 378) around the origin point while maintaining the wall's original length. In selecting adjacent pairs of walls, the length of each wall 374a, 376a must be greater than the minimum wall length and less than the maximum wall length to avoid snapping/merging wall segments that make up a curve.

The auto straighten module 120 will apply the correction (1), (2) (3) or (4) that impacts the fewest surrounding features.

Another type of wall inaccuracy is spacing between walls i.e., non-existent space added between walls, in the floorplan. Referring to FIG. 3D shown therein are diagrams of an automatic correction to wall spacing inaccuracies, according to an embodiment. As shown in diagram 380, adjacent wall segments 386, 388 in the 2D top down floorplan generated by the scanning application 114 do not have a common vertex and have a space 383 between them that is too small for a human to traverse. If the distance between the walls 386, 388 is less than the maximum wall close distance, line segments are added to close off the space 383. In diagram 382, the auto straighten module 120 projects wall endpoints 385, 387 onto opposing wall segments 386, 388. If a distance between the original endpoint position and the projected endpoint position is less than the maximum wall close distance, line segments are added to the endpoints 385, 387 to close off the space 383 between the wall segments 386, 388 resulting in the wall 390 shown in diagram 384.

The auto straighten module 120 can also straighten hallways (i.e., a pair of parallel walls represented as parallel line segments) similar to straightening walls as explained above. Hallways are pairs of parallel walls that do not have a common vertex position, and a distance between a wall endpoint projected onto the opposing wall is greater than the minimum hallway width and less than the maximum hallway width. The difference in line angles making up the walls of the hallway is measured, and if the angle is within a maximum hallway angle snap, one or both of the wall angles are adjusted so the angle between them becomes 0. The auto straightening module 120 will perform the angle adjustment that impacts the fewest surrounding features.

The scanning application 114 may also have difficulty in identifying certain architectural features in a space, in particular features such as columns, that span large distances or the entirety of the space. As such, the column may be incorrectly identified as a wall or wall segment which in turn affects the alignment of the actual walls of the space.

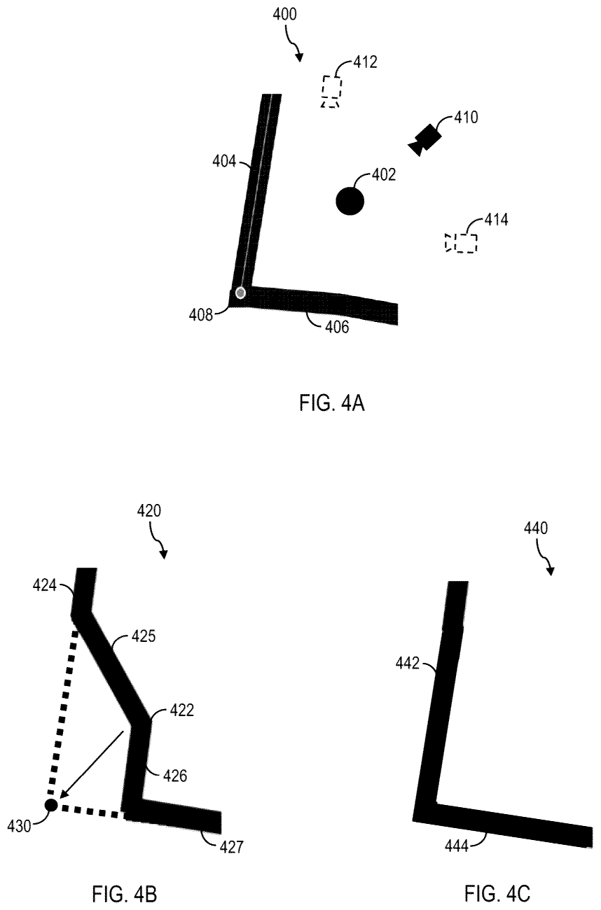

Referring to FIG. 4A, shown therein is a diagram a scanned space 400 including a column 402, according to an embodiment. The space 400 further includes two walls 404, 406 that meet at a corner 408. A scanning device 410 (i.e., the device 100 in FIG. 1) is positioned within the space 400 and oriented to facing the column 402 and walls 404, 406 during scanning of the space 400. The position of the column 402 between the scanning device 410 and the walls 404, 406, may occlude a portion of each wall 404, 406 from the scanning device 410 during scanning. Consequently, a 2D floorplan of the space (FIG. 4B), that is generated by the scanning application 114, includes several inaccuracies.

Referring to FIG. 4B, shown therein is a 2D floorplan 420 of the scanned space 400 shown in FIG. 4A. The floorplan 420 includes several inaccuracies when compared to the scanned space 400 in FIG. 4A: 1) the column 402 is a corner 422; 2) the walls 404 and 406 are not perpendicular and are broken into several wall segments 424, 425, 426, 427; and 3) the overall dimensions of the space is decreased because of 1) and 2). The inaccuracies can be manually corrected by the user in the floorplan editor 116 as explained above. For example, the corner 422 can be selected and dragged towards a point 430 corresponding to the actual position of the corner 408 in the space 400 until the line segments 425, 426 snap to align with the line segments 424, 427, respectively, to form perpendicular straight lines 442, 444 in a corrected 2D floorplan 440 shown in FIG. 4C.

According to other embodiments, the above-noted inaccuracies may be addressed during scanning of the space 400. Referring again to FIG. 4A, the device 410 may display a prompt (see FIG. 2G) instructing the user to scan columns more carefully, or from multiple positions 412, 414 within the space. According to another embodiment, when a potential column is detected by the scanning application 114, a prompt (see FIG. 2D) is displayed on the device 410 for the user to confirm whether the detected feature is a column or not.

Errors in feature detection can also occur during scanning of a space. For example, an entrance may be incorrectly detected and labeled as a window by the scanning application 114, or vice-versa. Such incorrectly detected features can be edited using the floorplan editor 116.

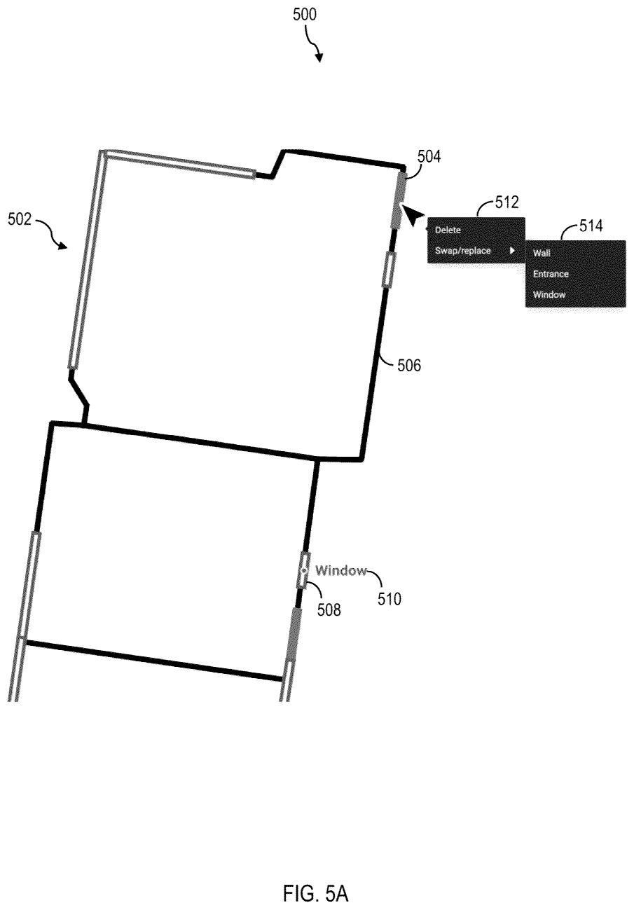

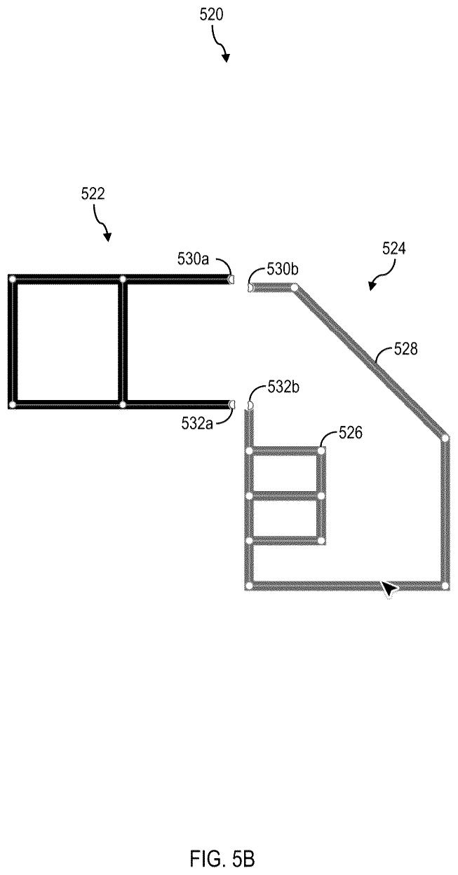

Referring to FIG. 5A, shown therein is an exemplary user interface 500 for feature editing in the floorplan editor 116, according to an embodiment. The user interface 500 displays a 2D floorplan 502. The floorplan 502 includes features of a scanned space e.g., walls, entrances, windows. For brevity, one representative entrance 504, one representative window 508, and one representative wall 506 are shown. The features 504, 506, 508 may be labelled or stylized differently to differentiate between features of the same type and different types. For examples, all windows may have a blue box outline, all walls may be black lines and all entrances may be red rectangles. The features may include text labels 510.

The features 504, 506, 508 are selectable, resizable, removable and swappable. A feature (i.e., entrance 504) when selected, opens a drop-down menu 512 of options to delete the feature or replace the feature with another feature. If the option to replace the feature is selected another drop-down menu 514 opens with options to replace the selected feature with another feature. Features that were missed during a scan (or not detected during the scan) can also be added to the floorplan 502 (not shown) using the floorplan editor 116.

According to some embodiments, features in the floorplan editor 116, such as walls 506, are further editable to define dimensions (e.g., height) of the wall 506. For example, when the wall 506 is selected, a drop-down menu of wall heights may be displayed for selection by the user. In another example, a user may be able to define the height of the wall 506 after selecting it, by entering a height (e.g., 10 ft.)

FIG. 5B shows an exemplary user interface 520 for combining floorplans in the floorplan editor 116, according to an embodiment. As explained above, a scan may be paused and restarted for several reasons. For example, once the entirety of a space is scanned, the scan may be stopped to move to an adjacent space. Generating a floorplan of a large space (e.g., a factory floor), or a floorplan comprising multiple smaller spaces (e.g., a floor of an office building) may thus require multiple scans to fully capture the entirety of the larger space.

Each scan creates a separate 2D floorplan 522, 524 of a scanned space. To create an overall floorplan of a larger space, the separate floorplans 522, 524 must be combined. The floorplan editor 116 is configured to allow snapping together of separate floorplans 522, 524 at vertices. Each floorplan 522, 524 can be independently dragged and dropped to orient/position it relative to another floorplan 522, 524 to manually align the floorplans as required. Individual vertices 526 (i.e., corners) and lines 528 (i.e., walls) can be manually adjusted, if required, to better align the floorplans 522, 524 in the same manner as described for the adjusting wall inaccuracies in FIGS. 3A-3B. When separate floorplans 522, 524 are brought close together, if there are corresponding vertices 530a, 530b, 532a, 532b on each floorplan, each vertex 530a, 530b, 532a, 532b becomes “magnetic” and snaps to its partner vertex on the opposing floorplan.

According to an embodiment, the floorplan editor 116 is configured to automatically stich or combine the separate floorplans 522, 524 at one or more common reference points. A common reference point is an area or a feature (e.g., an entrance, a wall) common to both floorplans.

It is to be noted that in the 2D floorplans 522, 524, and the features shown therein, are preferably represented as LineStrings rather than polygons. LineStrings are one-dimensional objects defined by two points (i.e., vertices in the floorplan) and the line segment connecting them; polygons are defined by at least 3 points. Accordingly, LineString manipulation is simpler and faster than polygonal manipulation since fewer overall points are manipulated. This results in lower memory requirements when manipulating line strings compared to polygons. A further benefit is that it is generally easier to identify features/objects as discrete line strings as opposed to polygons which must be further labelled.

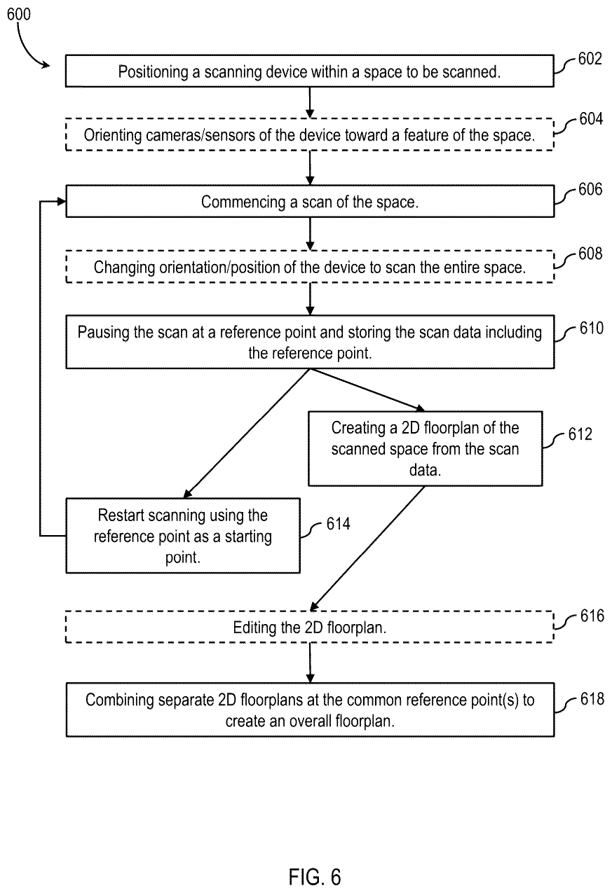

FIG. 6 is a flow chart of a method 600 for combining separate scans of multiple spaces to create a floorplan, according to an embodiment. The method may be implemented using the device 100 in FIG. 1. For reference the elements from FIG. 1 are indicated in parenthesis.

At 602, the device (100) is positioned within a space to be scanned. The space is preferably an indoor space.

In some embodiments, at 604, a user orients the cameras/sensors (104) of the device (100) toward a feature (e.g., an entrance). Step 604 may be done in response to a prompt on the display (108) instructing the user to point the camera at the feature to commence a scan.

At 606, a scan of the space is commenced. The scan may be commenced manually by the user. Where step 604 is performed, step 606 may be performed automatically to start the scan when the cameras/sensors (104) are pointed at the feature.

At 608, the orientation and/or position of the device (100) is changed to scan the entire area. The user will change the orientation/position of the device (100), as required, to scan the entirety of the space. While scanning, the user can view the preview of the scan (see FIGS. 2B, 2C) on the display (204) to get an indication of what areas of the space have been successfully scanned and which areas need to be scanned.

At 610, the scan is stopped/paused, scan data (118) is saved and a scan end point is saved as a reference point. The scan may be stopped/paused by any one of the following 1) the user manually stops the scan when the entire space has been scanned; 2) the scanning application (114) automatically stops the scan when it determines the entire space has been scanned and displays a prompt indicating the same; 3) the user pauses the scan in response to a prompt that the device (100) resources, in particular the memory (110) is nearly depleted; 4) the scanning application (114) automatically stops the scan when it determines that the device (100) resources, in particular the memory (110), is nearly depleted and displays a prompt indicating the same; or 5) the user moves the device (100) out of the space through a entrance (e.g., the user walks out the entrance while the device is scanning) and the scanning application (114) automatically pauses the scan.

At 612, the scanning application (114) generates a 2D floorplan of the scanned space from the scan data (118).

Concurrent to or following step 612, at 614, scanning is recommenced using the reference point saved at step 610 as the starting point. The device (100) may prompt the user to orient the cameras/sensors (104) toward the reference point to begin the scan. The device (100) may generate a ghost image of the reference point superimposed on the camera view on the display (108) to guide the user to orient the cameras/sensors (104) at the reference point. When the ghost image of the reference point aligns with the actual reference point on the camera view, scanning recommences automatically. For example, in an embodiment where scanning is paused at step 610 by the user walking through an entrance with the scanning device (100), the reference point will be the entrance. To recommence scanning, the user orients the cameras/sensors (104) toward the entrance and when the ghost image of the entrance aligns with the camera view of the actual entrance on the display (108), scanning recommences automatically.

Following step 614, the method 600 loops through steps 608, 610 and 614 for the unscanned spaces/areas that are required to be scanned.

In some embodiments, at 616 the 2D floorplan(s) may be opened in the floorplan editor (116) to edit, correct or annotate the floorplan. Corrections may be performed manually by the user. Corrections may be performed automatically by the floorplan editor (116) when prompted by the user.

At 618, separate floorplans of the various scanned spaces are stitched or combined to create an overall floorplan in the floorplan editor (116). The separate floorplans may be combined manually by the user. The separate floorplans may be combined automatically by the floorplan editor (116) based on common reference points in one or more separate floorplans.

While the above description provides examples of one or more apparatus, methods, or systems, it will be appreciated that other apparatus, methods, or systems may be within the scope of the claims as interpreted by one of skill in the art.

1. A computer-implemented method for generating a floorplan from scans of different areas, the method comprising:
commencing a first scan of a space by a scanning device to generate first scan data;
pausing the first scan at a reference point, wherein first scan data includes the reference point;
commencing a second scan of the space at the reference point to generate second scan data, wherein the second scan covers an area in the space not substantially scanned in first scan;
stopping the second scan; and
combining the first scan data and the second scan data at the reference point common to the first scan and the second scan to generate the floorplan.

2. The method of claim 1, further comprising:
identifying an architectural feature of the space as a starting point for the first scan.

3. The method of claim 2, further comprising:
displaying, on a display of the scanning device, a prompt to direct sensors of the scanning device to the architectural feature.

4. The method of claim 1, further comprising:
identifying a second architectural feature of the space as the reference point.

5. The method of claim 4, further comprising:
displaying, on a display of the scanning device, an outline of the reference point superimposed on a view captured by the scanning device.

6. The method of claim 1, further comprising:
detecting a memory of the scanning device is near depletion; and
displaying, on a display of the scanning device, a prompt to pause the first scan.

7. The method of claim 1, further comprising:
displaying, on a display of the scanning device, a floorplan preview superimposed on a view captured by the scanning device during the first scan and the second scan.

8. The method of claim 1, further comprising:
providing, on a display of the scanning device, an editor interface for editing the first scan data and the second scan data.

9. The method of claim 1, further comprising:
identifying wall inaccuracies in the first scan data and the second scan data; and
correcting the wall inaccuracies using predefined variables for polygon comparison.

10. A scanning device, comprising:
one or more sensors for scanning a space;
a display for displaying a view captured by the one or more sensors;
a storage unit for storing scan data;
a memory for storing processor-executable instructions; and
one or more processors, wherein execution of the processor-executable instructions by the one or more processors causes the scanning device to:
commence a first scan of the space;
pause the first scan at a reference point;
store first scan data including the reference point;
commence a second scan of the space at the reference point, wherein the second scan covers an area in the space not substantially scanned in first scan;
stop the second scan;
store second scan data; and
combine the first scan data and the second scan data at the reference point common to the first scan and the second scan to generate the floorplan.

11. The scanning device of claim 10, wherein the one or more sensors comprise at least a camera and a depth sensor.

12. The scanning device of claim 10 wherein execution of the processor-executable instructions by the one or more processors further causes the scanning device to:
identify an architectural feature of the space as a starting point for the first scan.

13. The scanning device of claim 12, wherein execution of the processor-executable instructions by the one or more processors further causes the scanning device to:
display, on the display of the scanning device, a prompt to direct sensors of the scanning device to the architectural feature.

14. The scanning device of claim 10, wherein execution of the processor-executable instructions by the one or more processors further causes the scanning device to:
identify a second architectural feature of the space as the reference point.

15. The scanning device of claim 14, wherein execution of the processor-executable instructions by the one or more processors further causes the scanning device to:
display, on the display of the scanning device, an outline of the reference point superimposed on the view captured by the one or more sensors.

16. The scanning device of claim 10, wherein execution of the processor-executable instructions by the one or more processors further causes the scanning device to:
detect the memory of the scanning device is near depletion; and
display, on the display of the scanning device, a prompt to pause the first scan.

17. The scanning device of claim 10, wherein execution of the processor-executable instructions by the one or more processors further causes the scanning device to:
display, on a display of the scanning device, a floorplan preview superimposed on a view captured by the one or more sensors during scanning.

18. The scanning device of claim 10, wherein execution of the processor-executable instructions by the one or more processors further causes the scanning device to:
provide an editor interface for editing the first scan data and the second scan data.

19. The scanning device of claim 10, wherein execution of the processor-executable instructions by the one or more processors further causes the scanning device to:
identify wall inaccuracies in the first scan data and the second scan data; and
correct the wall inaccuracies using predefined variables for polygon comparison.
